(19) United States
(12) Patent Application Publication
(10) Pub. No.: US 2026/0262488 A1
(43) Pub. Date: Sep. 3, 2026

(54) FILL PATTERN FOR ELECTROMAGNETIC DEVICES AND HIGH-FREQUENCY CIRCUITS

(71) Applicant: QUALCOMM Incorporated, San Diego, CA (US)

(72) Inventors: Omkar Rajeev NAGESHKAR, La Jolla, CA (US); Hai HUANG, San Jose, CA (US); Harmeet Singh SOBTI, San Diego, CA (US); Ning YUAN, San Diego, CA (US); Wenjun LIU, San Diego, CA (US); Jeongil Jay KIM, San Diego, CA (US)

(21) Appl. No.: 19/069,091

(22) Filed: Mar. 3, 2025

(51) Int. Cl. H01L 23/522; H01L 23/528; H01L 23/66

(52) U.S. Cl. CPC H10W 20/497; H10W 20/42; H10W 20/427; H10W 20/43; H10W 20/435; H10W 44/20

(57) ABSTRACT

A chip includes a first inductor and fill cells below the first inductor. Each of the fill cells includes respective first elongated members extending in a first direction, wherein the respective first elongated members are spaced apart in a second direction perpendicular to the first direction.

### BACKGROUND

### Field

Aspects of the present disclosure relate generally to fill patterns, and, more particularly, to fill patterns for electromagnetic devices and high-frequency circuits.

### Background

Electromagnetic (EM) devices and high-frequency circuits may be integrated on a chip (i.e., die) for various applications. For example, the EM devices may include inductors. The inductors may be used to implement an inductor-capacitor (LC) tuned circuit (e.g., for use in a filter, an amplifier, a voltage-controlled oscillator (VCO), and/or another type of circuit). The inductors may also be used to implement a transformer for providing electromagnetic coupling between circuits.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

An aspect relates to a chip. The chip includes a first inductor and fill cells below the first inductor. Each of the fill cells includes respective first elongated members extending in a first direction, wherein the respective first elongated members are spaced apart in a second direction perpendicular to the first direction.

### BRIEF DESCRIPTION OF THE DRAWINGS

FIG. 1 shows a side view of an example of a chip including metal layers and vias according to certain aspects of the present disclosure.

FIG. 2 shows a top view of an exemplary inductor according to certain aspects of the present disclosure.

FIG. 3 shows a top view of a fill cell according to certain aspects of the present disclosure.

FIG. 4A shows a top view of a first layer of an exemplary fill cell according to certain aspects of the present disclosure.

FIG. 4B shows a top view of a second layer of the exemplary fill cell according to certain aspects of the present disclosure.

FIG. 4C shows a top view of a third layer of the exemplary fill cell according to certain aspects of the present disclosure.

FIG. 4D shows a top view of a fourth layer of the exemplary fill cell according to certain aspects of the present disclosure.

FIG. 5A shows a top view of the first layer and the second layer of the exemplary fill cell according to certain aspects of the present disclosure.

FIG. 5B shows a top view of the second layer and the third layer of the exemplary fill cell according to certain aspects of the present disclosure.

FIG. 5C shows a top view of the third layer and the fourth layer of the exemplary fill cell according to certain aspects of the present disclosure.

FIG. 6 shows a top view in which multiple instances of the exemplary fill cell are used to fill an open space below a loop inductor according to certain aspects of the present disclosure.

FIG. 7 shows a top view in which multiple instances of the exemplary fill cell are used to fill an open space below a spiral inductor according to certain aspects of the present disclosure.

FIG. 8 shows a top view of an inductor overlapping the inductor of FIG. 7 to form a transformer according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

A chip may include many devices integrated on the chip including active devices (e.g., transistors) formed in a front end of line (FEOL) of the chip. The chip may also include a stack of metal layers formed in a back end of line (BEOL) of the chip, which is above the FEOL. The metal layers may be patterned to provide signal routing and power distribution for the active devices. One or more of the metal layers may also be patterned to form one or more electromagnetic (EM) devices (e.g., one or more inductors).

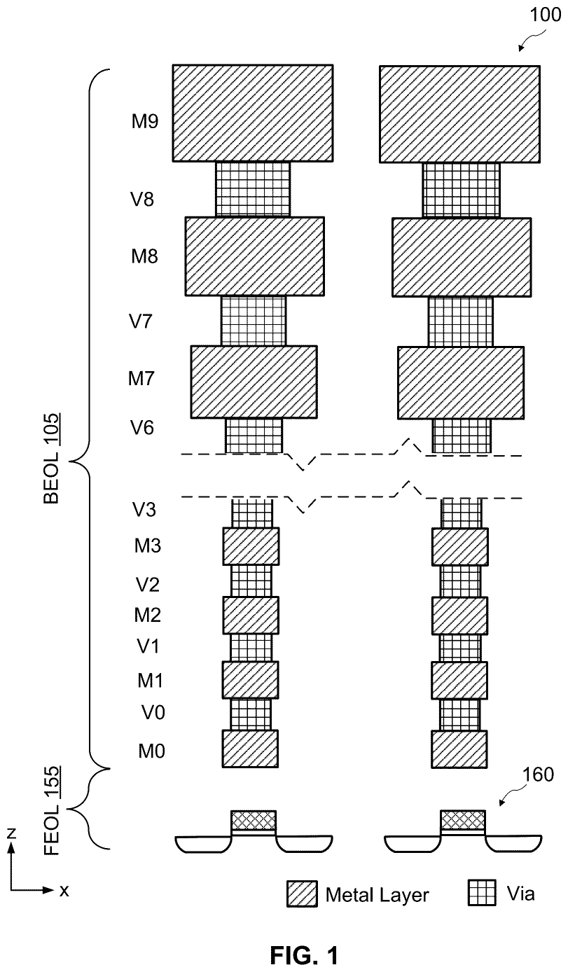

FIG. 1 shows a side view of an example of a BEOL 105 of a chip 100. The BEOL 105 is formed above the FEOL 155 of the chip 100, which may include active devices 160. In FIG. 1, the active devices 160 are depicted as planar transistors for simplicity. However, it is to be appreciated that the active devices 160 may include other types of transistors such as FinFETs, gate-all-around transistors, etc. The FEOL 155 may be formed on a semiconductor substrate (not shown).

As shown in FIG. 1, the BEOL 105 includes metal layers (also referred to as a metal stack). The metal layers may be patterned (e.g., using lithography and etching) to provide signal routing and/or power distribution. One or more of the metal layers may be patterned to form one or more EM devices (e.g., one or more inductors), as discussed further below.

In the example shown in FIG. 1, the bottom-most metal layer is referred to as metal layer M0. The metal layer immediately above metal layer M0 is referred to as metal layer M1, the metal layer immediately above metal layer M1 is referred to as metal layer M2, the metal layer immediately above metal layer M2 is referred to as metal layer M3, and so forth. In the example shown in FIG. 1, the metal layers go up to metal layer M9. However, it is to be appreciated that the BEOL 105 may include one or more additional metal layers above metal layer M9. Note that metal layers M4 to M6 are not shown in FIG. 1 for ease of illustration. It is to be appreciated that the BEOL 105 is not limited to the number of metal layers shown in the example in FIG. 1 and that the BEOL 105 may include a smaller number of metal layers or a larger number of metal layers in other examples.

It is to be appreciated that the present disclosure is not limited to the nomenclature in which the bottom-most metal layer is referred to as metal layer M0. For instance, in another example, the bottom-most metal layer may be referred to as metal layer M1 instead of metal layer M0. Also, it is to be appreciated that one or more of the metal layers may be designated with a letter other than M.

In certain aspects, the upper metal layers have larger thicknesses than the lower metal layers. For example, in the example shown in FIG. 1, metal layer M9 has a larger thickness than the bottom-most metal layer M0 (which provides routing to individual active devices). It is to be appreciated that the metal layers M0 to M9 are not necessarily drawn to scale in FIG. 1 and that the relative thicknesses of the metal layers may differ from the example shown in FIG. 1.

The BEOL 105 also includes vias that provide coupling between the metal layers. The vias include vias V0 to V8. In this example, the vias V0 provide coupling between metal layer M0 and metal layer M1, the vias V1 provide coupling between metal layer M1 and metal layer M2, the vias V2 provide coupling between metal layer M2 and metal layer M3, and so forth. Metal layer M0 may be coupled to the active devices 160 in the FEOL 155 by vias (not shown) between metal layer M0 and the active devices 160.

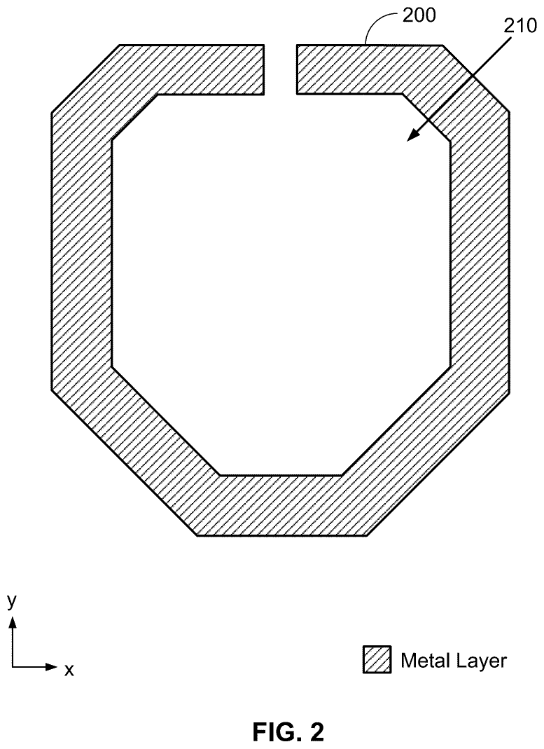

FIG. 2 shows a top view of an example of an inductor 200 that may be integrated on the chip 100 according to certain aspects. The inductor 200 may include a planar loop inductor (shown in FIG. 2) or another type of inductor. The inductor 200 may be formed in one of the upper metal layers such as metal layer M7, M8, M9 or another upper metal layer (e.g., using lithography and etching).

In this example, the loop of the inductor 200 surrounds an area 210, which is shown as being empty in FIG. 2. In practice, the portion of the chip 100 below the area 210 cannot be empty. This is because the portion of the chip 100 below the area 210 needs to meet certain density requirements (e.g., metal density requirements) specified by design rule checking (DRC). The DRC is used to verify that the chip layout meets constraints imposed by the process technology used to fabricate the chip 100. For example, the DRC may include a metal density requirement for a metal layer specifying a minimum amount of metal within a given chip area, which prohibits a large empty space. As used herein, “below” means lower in a direction toward the FEOL 155. For example, metal layers M0 to M6 are below metal layer M7. In general, a metal layer with a lower numerical designation is below a metal layer with a higher numerical designation.

In order to meet density requirements (e.g., metal density requirements) of the DRC, the chip layout may include fills within the portion of the chip 100 below the area 210. In the past, layout designers performed manual hand-drawn fills to meet the density requirements. However, this approach is no longer feasible due to the time-intensive nature of manual fill operations and the increasing complexity of the DRC in advanced process technologies (e.g., process nodes).

To streamline the fill operation, multiple instances of a fill cell defined in a cell library may be placed within the portion of the chip 100 below the area 210. However, the fill cells may introduce parasitic capacitance which degrades the performance of the inductor 200. Accordingly, it is desirable for the fill cells to reduce the impact of the parasitic capacitance while still meeting the density requirements of the DRC.

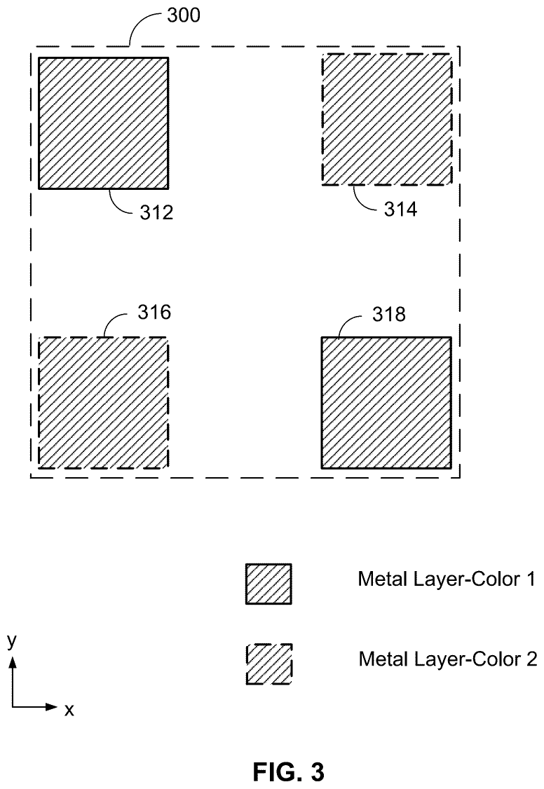

FIG. 3 shows a top view of an example of a fill cell 300 according to certain aspects. Multiple instances of the fill cell 300 may be placed within the portion of the chip 100 below the area 210 to meet the density requirements of the DRC.

In the example shown in FIG. 3, the fill cell 300 includes a first metal square 312, a second metal square 314, a third metal square 316, and a fourth metal square 318 located at different corners of the fill cell 300. The metal squares 312, 314, 316, and 318 shown in FIG. 3 may be formed in a metal layer (e.g., using lithography and etching) of the chip 100. In certain aspects, the fill cell 330 may be formed in multiple metal layers (e.g., metal layers M0 to M3) of the chip 100 in which the fill cell 300 includes an instance (i.e., copy) of the metal squares 312, 314, 316, and 318 in each of the metal layers.

In certain aspects, each of the metal squares 312, 314, 316, and 318 has a size approximately equal to one unit cell. As used herein, a “unit cell” may correspond to the smallest possible fill shape or fill pattern in a cell library, which can be replicated across a fill region to meet the DRC. In this example, the metal squares 312, 314, 316, and 318 may be spaced apart to reduce the metal density of the fill cell 300 (e.g., to reduce the impact of parasitic capacitance on performance) while still meeting one or more density requirements (e.g., metal density requirement) of the DRC. For example, the metal density of the fill cell 300 may be within a metal density range that meets both the metal density requirement for performance (e.g., inductor performance) and the metal density requirement of the DRC.

In certain aspects, the metal squares 312, 314, 316, and 318 are patterned in a metal layer using double patterning in which two lithographic masks are used to pattern the metal layer (e.g., to enhance feature density). Each mask may be referred to as a color. In this example, the DRC may include a color balance density requirement that specifies a maximum density difference between the different colors. In the example in FIG. 3, the first metal square 312 and the fourth metal square 318 are patterned using a first color (i.e., first mask) and the second metal square 314 and the third metal square 316 are patterned using a second color (i.e., second mask). In this example, the squares patterned with the same color are placed at opposite corners of the fill cell 300. Thus, the first color and the second color are evenly distributed among the metal squares 312, 314, 316, and 318. This provides the fill cell 310 with color balance, which helps meet the color balance density requirement of the DRC. In FIG. 3, the squares patterned with the first color are shown with solid boundaries and the squares patterned with the second color are shown with dashed boundaries.

The fill cell 300 meets the density and symmetry requirements of an EM device (e.g., the inductor 200) while also meeting the metal density requirement and the color balance density requirement of the DRC. However, the fill cell 300 may not meet one or more other requirements of the DRC. For example, the square pattern of the fill cell 300 may cause the fill cell 300 to violate a line edge density requirement of the DRC, which may require a minimum density of metal edges for a given area. In addition, the fill cell 300 may cause a violation of a maximum empty space requirement of the DRC due to the relatively large size of the fill cell 300. The large size of the fill cell 300 is due to the fill cell 300 including four squares to meet the color balance density requirement where each of the squares has the size of one unit cell. In this example, the large size of the fill cell 300 makes it difficult for multiple instances of the fill cell 300 to fill in areas with tight corners, which can lead to large empty spaces in the vicinity of the tight corners.

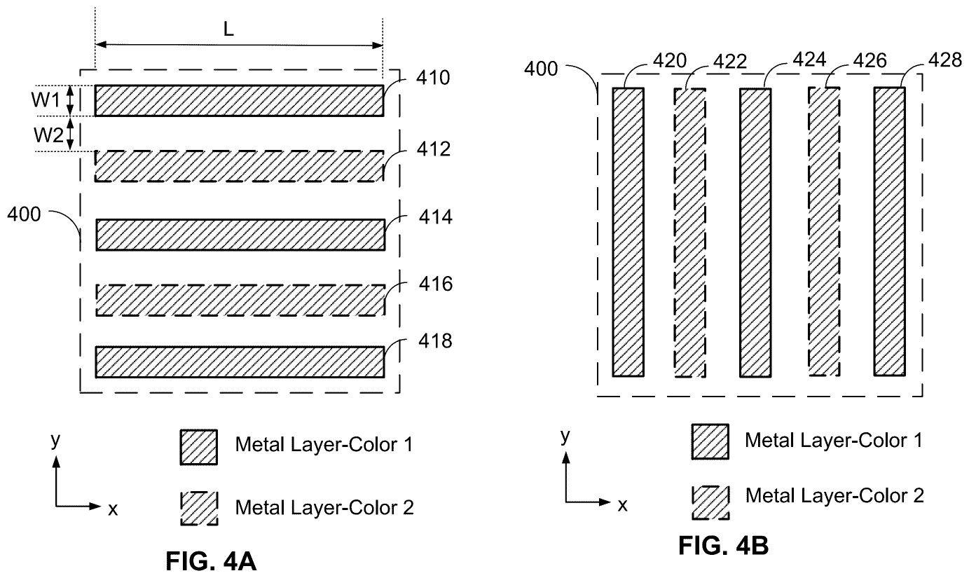

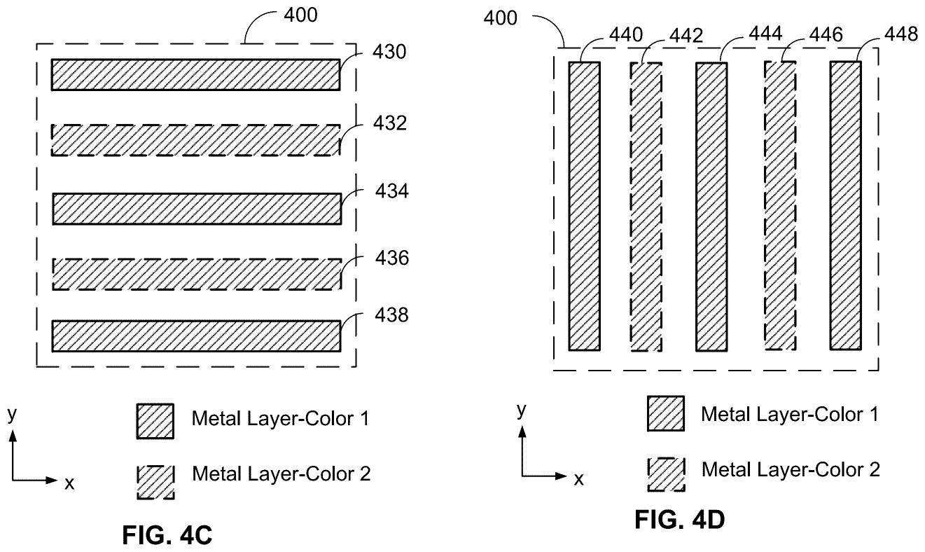

FIGS. 4A to 4D show different layers of an exemplary fill cell 400 according to certain aspects of the present disclosure. As discussed further below, the fill cell 400 addresses the line edge density requirement and the empty space requirement of the DRC while also meeting the metal density requirement and the color balance density requirement of the DRC. The fill cells 400 are not used for signal routing and are not used for power distribution.

In this example, the fill cell 400 includes a stack of metal structures formed in metal layers M0 to M3 (e.g., using lithographic and etching). FIG. 4A shows the metal structures formed in metal layer M0, FIG. 4B shows the metal structures formed in metal layer M1, FIG. 4C shows the metal structures formed in metal layer M2, and FIG. 4D shows the metal structures formed in metal layer M3. It is to be appreciated that the cell 400 is not limited to metal layers M0 to M3. For example, in some implementations, the cell 400 may include additional metal structures formed in one or more additional metal layers above metal layer M3 (e.g., metal layers M4 to M7).

Referring to FIG. 4A, the fill cell 400 includes elongated members 410, 412, 414, 416, and 418 formed in metal layer M0. The elongated members 410, 412, 414, 416, and 418 extend in the x direction and are spaced apart in the y direction. In this example, each of the elongated members 410, 412, 414, 416, and 418 has a length of L and a width of W1, and the elongated members 410, 412, 414, 416, and 418 are spaced apart by a distance of W2 in the y direction. In the example in FIG. 4A, the lengthwise direction of the elongated members 410, 412, 414, 416, and 418 is in the x direction.

The elongated members 410, 412, 414, 416, and 418 have rectangular shapes, which increase line edge density compared with the square shapes shown in FIG. 3. This is because rectangular shapes are able to provide a larger number of metal edges than square shapes in the same area. The increased line edge density allows the fill cell 400 to meet the line edge density of the DRC.

The elongated members 410, 412, 414, 416, and 418 may be sized and/or spaced apart to reduce the metal density of the fill cell 400 (e.g., to reduce the impact of parasitic capacitance on performance) while still meeting one or more density requirements (e.g., metal density requirement) of the DRC. For example, the metal density may be reduced by making the distance W2 (i.e., spacing) between the elongated members 410, 412, 414, 416, and 418 greater than the width W1 of each of the elongated members 410, 412, 414, 416, and 418 in the y direction. In certain aspects, the elongated members 410, 412, 414, 416, and 418 may be sized and/or spaced apart to provide a metal density in the range of 15 to 30 percent (e.g., in metal layer M0), which may meet both the metal density requirement for performance (e.g., inductor performance) and the metal density requirement of the DRC. However, it is to be appreciated that the fill cell 400 is not limited to this exemplary density range. For example, the metal density range may alternatively be defined as the lowest possible density allowed by a foundry that does not violate width, length, spacing, and/or forbidden space requirements of the DRC. As used herein, the “metal density” of a fill cell is a percentage of the area of the fill cell including metal.

In this example, the elongated members 410, 412, 414, 416, and 418 are patterned in metal layer M0 using double patterning in which two lithographic masks are used to pattern metal layer M0 (e.g., to enhance feature density). Each mask may be referred to as a color. In this example, the elongated members 410, 412, 414, 416, and 418 alternate between the different colors to facilitate color balancing in which the elongated members 410, 414, and 418 are patterned using a first color (i.e., first mask) and the elongated members 412 and 416 are patterned using a second color (i.e., second mask). In FIG. 4A, the elongated members patterned with the first color are shown with solid boundaries and the elongated members patterned with the second color are shown with dashed boundaries. Alternating the elongated members 410, 412, 414, 416, and 418 between the first color and the second color allows the fill cell 400 to meet the color balance density requirement of the DRC. Note that the color balance density requirement does not necessarily require that color densities be perfectly balanced. For example, the color balance density requirement may require that the density difference between the first color and the second color be equal to or less than a maximum allowable density difference.

In this example, the fill cell 400 may have a size of approximately one unit cell. This is significantly smaller than the fill cell 300 which includes four squares each having a size of approximately one unit cell. The smaller size of the fill cell 400 allows multiple instances of the fill cell 400 to more easily fill in areas with tight corners, which helps meet the empty space requirement of the DRC.

Referring to FIG. 4B, the fill cell 400 may also include elongated members 420, 422, 424, 426, and 428 formed in metal layer M1, which is above metal layer M0. The elongated members 420, 422, 424, 426, and 428 extend in the y direction and are spaced apart in the x direction. As discussed further below, the elongated members 420, 422, 424, 426, and 428 may be stacked above the elongated members 410, 412, 414, 416, and 418, in which the elongated members 420, 422, 424, 426, and 428 are orientated perpendicular to the elongated members 410, 412, 414, 416, and 418.

The elongated members 420, 422, 424, 426, and 428 have rectangular shapes, which increase line edge density for the reasons given above for the elongated members 410, 412, 414, 416, and 418. The elongated members 420, 422, 424, 426, and 428 may be sized and/or spaced apart to meet both the metal density requirement for performance (e.g., inductor performance) and the metal density requirement of the DRC. In certain aspects, the elongated members 420, 422, 424, 426, and 428 may be sized and/or spaced apart to provide a metal density in the range of 15 to 30 percent or another range (e.g., in metal layer M1). In certain aspects, the spacing between the elongated members 420, 422, 424, 426, and 428 is greater than the width of each of the elongated members 420, 422, 424, 426, and 428 in the x direction.

In this example, the elongated members 420, 422, 424, 426, and 428 are patterned in metal layer M1 using double patterning in which two lithographic masks are used to pattern metal layer M1 (e.g., to enhance feature density). In this example, the elongated members 420, 422, 424, 426, and 428 alternate between the different colors to facilitate color balancing in which the elongated members 420, 424, and 428 are patterned using a first color (i.e., first mask) and the elongated members 422 and 426 patterned using a second color (i.e., second mask). In FIG. 4B, the elongated members patterned with the first color are shown with solid boundaries and the elongated members patterned with the second color are shown with dashed boundaries. Alternating the elongated members 420, 422, 424, 426, and 428 between the first color and the second color allows the fill cell 400 to meet the color balance density requirement of the DRC.

Referring to FIG. 4C, the fill cell 400 may also include elongated members 430, 432, 434, 436, and 438 formed in metal layer M2, which is above metal layer M1. The elongated members 430, 432, 434, 436, and 438 extend in the x direction and are spaced apart in the y direction. As discussed further below, the elongated members 430, 432, 434, 436, and 438 may be stacked above the elongated members 420, 422, 424, 426, and 428, in which the elongated members 430, 432, 434, 436, and 438 are orientated perpendicular to the elongated members 420, 422, 424, 426, and 428.

The elongated members 430, 432, 434, 436, and 438 have rectangular shapes, which increase line edge density for the reasons given above for the elongated members 410, 412, 414, 416, and 418. The elongated members 430, 432, 434, 436, and 438 may be sized and/or spaced apart to meet both the metal density requirement for performance (e.g., inductor performance) and the metal density requirement of the DRC. In certain aspects, the elongated members 430, 432, 434, 436, and 438 may be sized and/or spaced apart to provide a metal density in the range of 15 to 30 percent or another range (e.g., in metal layer M2). In certain aspects, the spacing between the elongated members 430, 432, 434, 426, and 438 is greater than the width of each of the elongated members 430, 432, 434, 436, and 438 in the y direction.

In this example, the elongated members 430, 432, 434, 436, and 438 are patterned in metal layer M2 using double patterning in which two lithographic masks are used to pattern metal layer M2 (e.g., to enhance feature density). In this example, the elongated members 430, 432, 434, 436, and 438 alternate between the different colors to facilitate color balancing in which the elongated members 430, 434, and 438 are patterned using a first color (i.e., first mask) and the elongated members 432 and 436 patterned using a second color (i.e., second mask). In FIG. 4C, the elongated members patterned with the first color are shown with solid boundaries and the elongated members patterned with the second color are shown with dashed boundaries. Alternating the elongated members 430, 432, 434, 436, and 438 between the first color and the second color allows the fill cell 400 to meet the color balance density requirement of the DRC.

Referring to FIG. 4D, the fill cell 400 may also include elongated members 440, 442, 444, 446, and 448 formed in metal layer M3, which is above metal layer M2. The elongated members 440, 442, 444, 446, and 448 extend in the y direction and are spaced apart in the x direction. As discussed further below, the elongated members 440, 442, 444, 446, and 448 may be stacked above the elongated members 430, 432, 434, 436, and 438, in which the elongated members 440, 442, 444, 446, and 448 are orientated perpendicular to the elongated members 430, 432, 434, 436, and 438.

The elongated members 440, 442, 444, 446, and 448 have rectangular shapes, which increase line edge density for the reasons given above for the elongated members 410, 412, 414, 416, and 418. The elongated members 440, 442, 444, 446, and 448 may be sized and/or spaced apart to meet both the metal density requirement for performance (e.g., inductor performance) and the metal density requirement of the DRC. In certain aspects, the elongated members 440, 442, 444, 446, and 448 may be sized and/or spaced apart to provide a metal density in the range of 15 to 30 percent or another range (e.g., in metal layer M3). In certain aspects, the spacing between the elongated members 440, 442, 444, 446, and 448 is greater than the width of each of the elongated members 440, 442, 444, 446, and 448 in the x direction.

In this example, the elongated members 440, 442, 444, 446, and 448 are patterned in metal layer M3 using double patterning in which two lithographic masks are used to pattern metal layer M3 (e.g., to enhance feature density). In this example, the elongated members 440, 442, 444, 446, and 448 alternate between the different colors to facilitate color balancing in which the elongated members 440, 444, and 448 are patterned using a first color (i.e., first mask) and the elongated members 442 and 446 patterned using a second color (i.e., second mask). In FIG. 4D, the elongated members patterned with the first color are shown with solid boundaries and the elongated members patterned with the second color are shown with dashed boundaries. Alternating the elongated members 440, 442, 444, 446, and 448 between the first color and the second color allows the fill cell 400 to meet the color balance density requirement of the DRC.

As discussed above, the fill cell 400 is not limited to metal layers M0 to M3. For example, in some implementations, the cell 400 may include additional metal structures formed in one or more additional metal layers above metal layer M3. For example, in some implementations, the fill cell 400 may also include elongated members extending in the x direction in metal layer M4, elongated members extending in the y direction in metal layer M5, elongated members extending in the direction x in metal layer M6, and/or elongated members extending in the direction y in metal layer M7. Thus, the exemplary fill patterns shown in FIGS. 4A to 4D may be repeated for metal layers M4 to M7. In certain aspects, double patterning may not be used for metal layer M4 and above. In these aspects, the color balancing density requirement is not applicable to the metal layers M4 to M7, and the elongated members in each of the metal layers M4 to M7 may be patterned using one mask. However, it is to be appreciated that the present disclosure is not limited to this example.

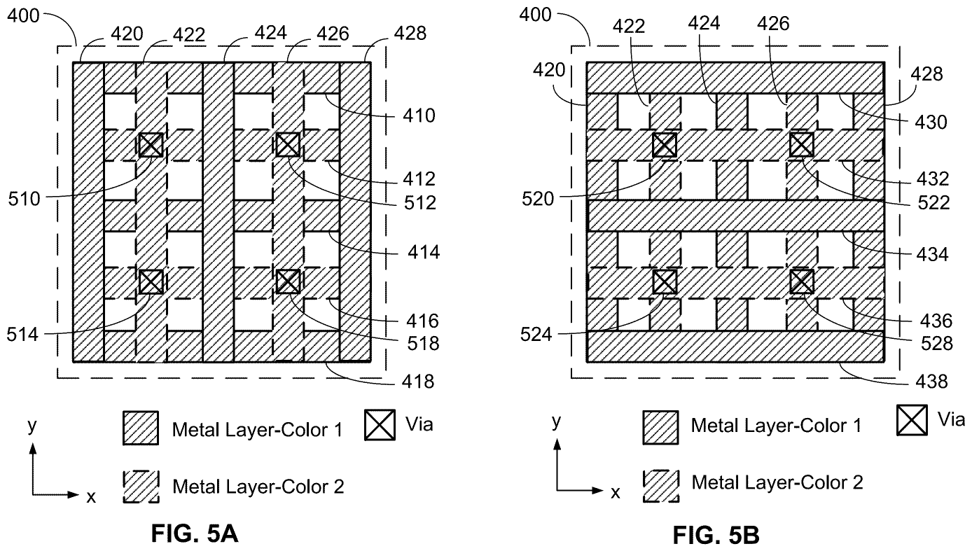

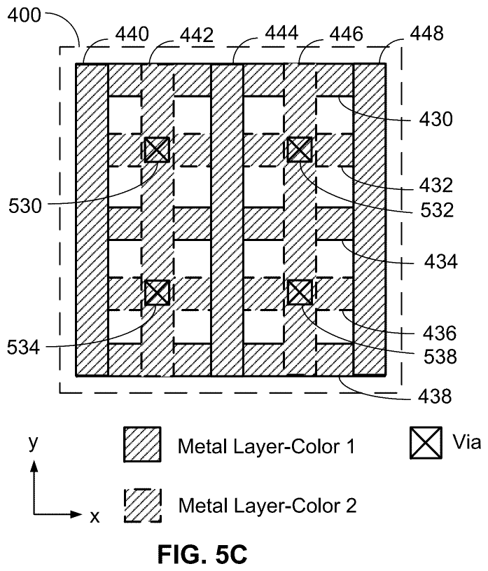

FIG. 5A shows a top view of an example in which the elongated members 420, 422, 424, 426, and 428 in metal layer M1 are stacked above the elongated members 410, 412, 414, 416, and 418 in metal layer M0. In this example, each of the elongated members 420, 422, 424, 426, and 428 extends over the elongated members 410, 412, 414, 416, and 418 in the y direction.

In certain aspects, the fill cell 400 also includes vias 510, 512, 514, and 516 (e.g., V0 in FIG. 1) between metal layer M1 and metal layer M0. The vias may be included, for example, to meet a via density requirement of the DRC. In the example shown in FIG. 5A, the via 510 is disposed between the elongated member 412 in metal layer M0 and the elongated member 422 in metal layer M1, the via 512 is disposed between the elongated member 412 in metal layer M0 and the elongated member 426 in metal layer M1, the via 514 is disposed between the elongated member 416 in metal layer M0 and the elongated member 422 in metal layer M1, and the via 518 is disposed between the elongated member 416 in metal layer M0 and the elongated member 426 in metal layer M1.

FIG. 5B shows a top view of an example in which the elongated members 430, 432, 434, 436, and 438 in metal layer M2 are stacked above the elongated members 420, 422, 424, 426, and 428 in metal layer M1. In this example, each of the elongated members 430, 432, 434, 436, and 438 extends over the elongated members 420, 422, 424, 426, and 428 in the x direction.

In certain aspects, the fill cell 400 also includes vias 520, 522, 524, and 526 (e.g., V1 in FIG. 1) between metal layer M2 and metal layer M1. The vias may be included, for example, to meet a via density requirement of the DRC. In the example shown in FIG. 5B, the via 520 is disposed between the elongated member 422 in metal layer M1 and the elongated member 432 in metal layer M2, the via 522 is disposed between the elongated member 426 in metal layer M1 and the elongated member 432 in metal layer M2, the via 524 is disposed between the elongated member 422 in metal layer M1 and the elongated member 436 in metal layer M2, and the via 528 is disposed between the elongated member 426 in metal layer M1 and the elongated member 436 in metal layer M2.

FIG. 5C shows a top view of an example in which the elongated members 440, 442, 444, 446, and 448 in metal layer M3 are stacked above the elongated members 430, 432, 434, 436, and 438 in metal layer M2. In this example, each of the elongated members 440, 442, 444, 446, and 448 extends over the elongated members 430, 432, 434, 436, and 438 in the y direction.

In certain aspects, the fill cell 400 also includes vias 530, 532, 534, and 536 (e.g., V2 in FIG. 1) between metal layer M3 and metal layer M2. The vias may be included, for example, to meet a via density requirement of the DRC. In the example shown in FIG. 5C, the via 530 is disposed between the elongated member 432 in metal layer M2 and the elongated member 442 in metal layer M3, the via 532 is disposed between the elongated member 432 in metal layer M2 and the elongated member 446 in metal layer M3, the via 534 is disposed between the elongated member 436 in metal layer M2 and the elongated member 442 in metal layer M3, and the via 538 is disposed between the elongated member 436 in metal layer M2 and the elongated member 446 in metal layer M3.

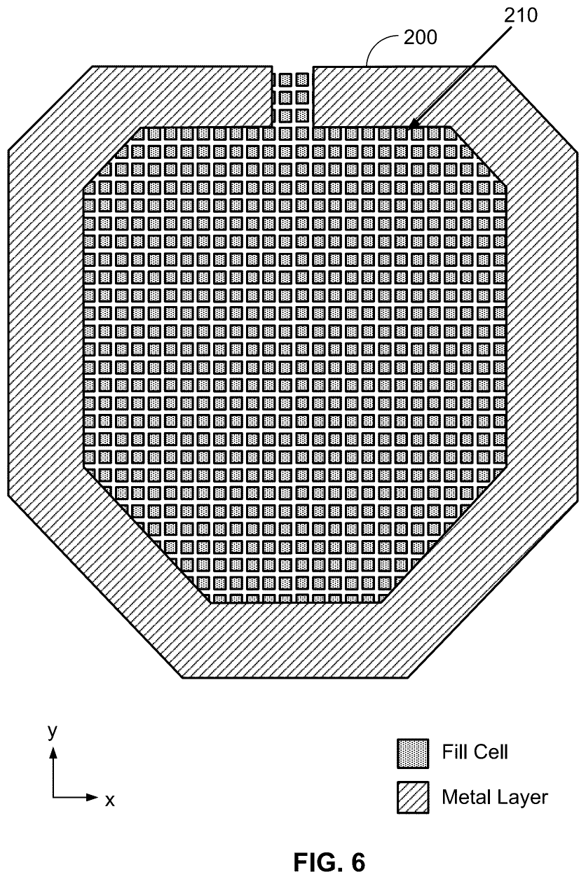

FIG. 6 shows a top view of an example in which multiple instances of the fill cell 400 are used to fill the space below the area 210 to meet the density requirements of the DRC. In this example, the area 210 is the area surrounded by the loop of the inductor 200. In FIG. 6, each instance of the fill cell 400 is depicted as a small square due to the small size of the fill cell 400 compared with the inductor 200. It is to be appreciated that the multiple instances of the fill cell 400 may be referred to as fill cells where each of the fill cells is an instance (i.e., copy) of the fill cell 400.

It is to be appreciated that FIG. 6 is not necessarily drawn to scale. For example, it is to be appreciated that the instances of the fill cell 400 may be smaller with respect to the inductor 200 than shown in FIG. 6. It is to be appreciated that instances of the fill cell 400 may be used to fill space below the inductor 200 and space below an area surrounding the inductor 200.

As discussed above, the inductor 200 may be formed in one of the upper metal layers such as metal layer M7, M8, M9 or another upper metal layer (e.g., using lithography and etching). In this example, the instances of the fill cell 400 may be formed in one or more of metal layers M0 to M6, which are below metal layer M7. However, it is to be appreciated that the present disclosure is not limited to this example. In general, the inductor 200 may be formed in a metal layer above the one or more metal layers in which the instances of the fill cell 400 are formed.

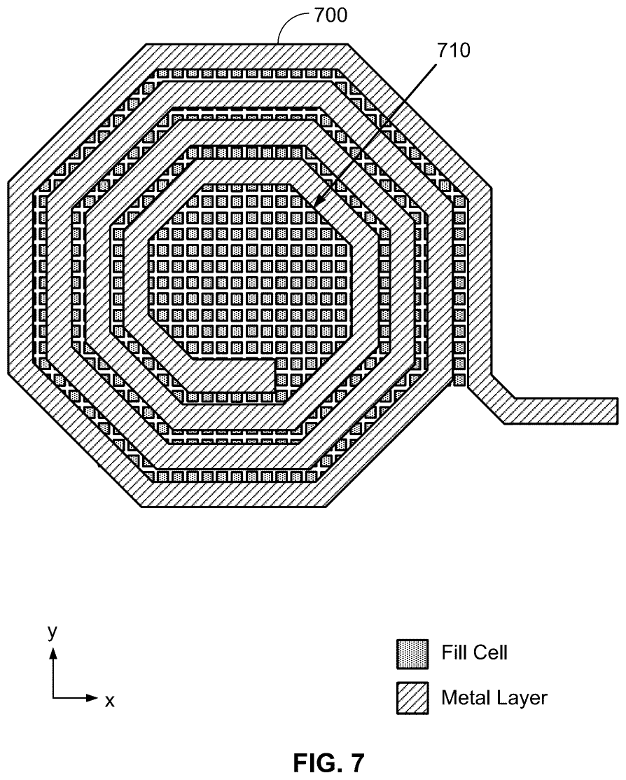

It is to be appreciated that the fill cell 400 is not limited to the exemplary inductor 200. In this regard, FIG. 7 shows a top view of a planar spiral inductor 700 according to certain aspects. The inductor 700 may be formed in one of the upper metal layers such as metal layer M7, M8, M9 or another upper metal layer (e.g., using lithography and etching).

FIG. 7 shows an example in which multiple instances of the fill cell 400 are used to fill the space below an area 710 surrounded by the inner loop of the inductor 700 to meet the density requirements of the DRC. In FIG. 7, each instance of the fill cell 400 is depicted as a small square due to the small size of the fill cell 400 compared with the inductor 700.

It is to be appreciated that FIG. 7 is not necessarily drawn to scale. For example, it is to be appreciated that the instances of the fill cell 400 may be smaller with respect to the inductor 700 than shown in FIG. 7. It is to be appreciated that instances of the fill cell 400 may be used to fill space below the inductor 700 and space below an area surrounding the inductor 700.

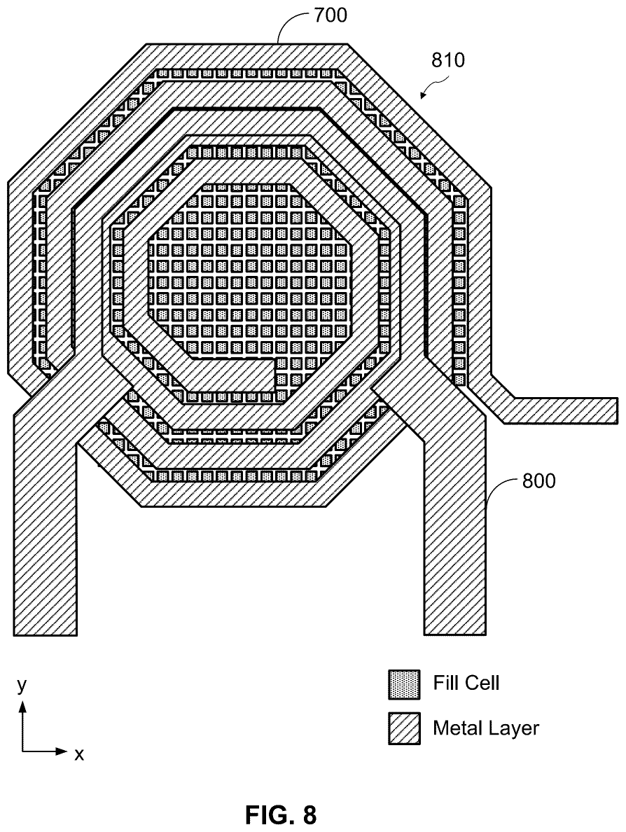

In certain aspects, the inductor 700 may be part of a transformer. In this regard, FIG. 8 shows an example of an inductor 800 overlapping the inductor 700 to form a transformer 810 in which the inductor 800 is electromagnetically coupled with the inductor 700. In this example, the inductor 800 is a planar inductor formed in a metal layer above the metal layer in which the inductor 700 is formed. However, it is to be appreciated that the present disclosure is not limited to this example. In the example in FIG. 8, one of the inductors 700 and 800 may provide the primary side of the transformer 810 and the other one of the inductors 700 and 800 may provide the secondary side of the transformer 810. It is to be appreciated that, in some implementations, the inductor 800 may overlap the exemplary inductor 200 to form a transformer.

Implementation examples are described in the following numbered clauses:
1. A chip, comprising:
   a first inductor; and
   fill cells below the first inductor, wherein each of the fill cells includes:
      respective first elongated members extending in a first direction, wherein the respective first elongated members are spaced apart in a second direction perpendicular to the first direction.
2. The chip of clause 1, wherein each of the fill cells has a metal density of between 15 percent to 30 percent.
3. The chip of clause 1 or 2, wherein, in each of the fill cells, a spacing between the respective first elongated members is greater than a width of each of the respective first elongated members.
4. The chip of any one of clauses 1 to 3, wherein each of the fill cells further comprises respective second elongated members extending over the respective first elongated members in the second direction, wherein the respective second elongated members are spaced apart in the first direction.
5. The chip of clause 4, wherein each of the fill cells further comprises respective vias disposed between the respective first elongated members and the respective second elongated members.
6. The chip of clause 4 or 5, wherein the respective first elongated members of each of the fill cells are formed in a first metal layer, and the respective second elongated members of each of the fill cells are formed in a second metal layer above the first metal layer.
7. The chip of clause 6, wherein each of the fill cells has a metal density of between 15 percent to 30 percent in each of the first metal layer and the second metal layer.
8. The chip of any one of clauses 4 to 7, wherein, in each of the fill cells, a spacing between the respective first elongated members is greater than a width of each of the respective first elongated members, and a spacing between the respective second elongated members is greater than a width of each of the respective second elongated members.
9. The chip of any one of clauses 4 to 8, wherein each of the fill cells further comprises respective third elongated members extending over the respective second elongated members in the first direction, wherein the respective third elongated members are spaced apart in the second direction.
10. The chip of clause 9, wherein each of the fill cells further comprises:
   respective first vias disposed between the respective first elongated members and the respective second elongated members; and
   respective second vias disposed between the respective second elongated members and the respective third elongated members.
11. The chip of clause 9 or 10, wherein the respective first elongated members of each of the fill cells are formed in a first metal layer, the respective second elongated members of each of the fill cells are formed in a second metal layer above the first metal layer, and the respective third elongated members of each of the fill cells are formed in a third metal layer above the second metal layer.
12. The chip of any one of clauses 9 to 11, wherein each of the fill cells further comprises respective fourth elongated members extending over the respective third elongated members in the second direction, wherein the respective fourth elongated members are spaced apart in the first direction.
13. The chip of clause 12, wherein, in each of the fill cells, a spacing between the respective first elongated members is greater than a width of each of the respective first elongated members, a spacing between the respective second elongated members is greater than a width of each of the respective second elongated members, a spacing between the respective third elongated members is greater than a width of each of the respective third elongated members, and a spacing between the respective fourth elongated members is greater than a width of each of the respective fourth elongated members.
14. The chip of clause 12 or 13, wherein each of the fill cells further comprises:
   respective first vias disposed between the respective first elongated members and the respective second elongated members;
   respective second vias disposed between the respective second elongated members and the respective third elongated members; and
   respective third vias disposed between the respective third elongated members and the respective fourth elongated members.
15. The chip of any one of clauses 12 to 14, wherein the respective first elongated members of each of the fill cells are formed in a first metal layer, the respective second elongated members of each of the fill cells are formed in a second metal layer above the first metal layer, the respective third elongated members of each of the fill cells are formed in a third metal layer above the second metal layer, and the respective third elongated members of each of the fill cells are formed in a fourth metal layer above the third metal layer.
16. The chip of clause 15, wherein each of the fill cells has a metal density of between 15 percent to 30 percent in each of the first metal layer, the second metal layer, the third metal layer, and the fourth metal layer.
17. The chip of any one of clauses 1 to 16, wherein the fill cells are disposed in a portion of the chip below an area surrounded by a loop of the first inductor.
18. The chip of clause 17, further comprising a second inductor overlapping the first inductor.
19. The chip of clause 17 or 18, wherein the first inductor comprises a planar loop inductor.
20. The chip of clause 17 or 18, wherein the first inductor comprises a spiral inductor.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. As used herein, below an inductor may include below an area surrounded by a loop of the inductor and/or below the loop of the inductor.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
a first inductor; and
fill cells below the first inductor, wherein each of the fill cells includes:
respective first elongated members extending in a first direction, wherein the respective first elongated members are spaced apart in a second direction perpendicular to the first direction.

2. The chip of claim 1, wherein each of the fill cells has a metal density of between 15 percent to 30 percent.

3. The chip of claim 1, wherein, in each of the fill cells, a spacing between the respective first elongated members is greater than a width of each of the respective first elongated members.

4. The chip of claim 1, wherein each of the fill cells further comprises respective second elongated members extending over the respective first elongated members in the second direction, wherein the respective second elongated members are spaced apart in the first direction.

5. The chip of claim 4, wherein each of the fill cells further comprises respective vias disposed between the respective first elongated members and the respective second elongated members.

6. The chip of claim 4, wherein the respective first elongated members of each of the fill cells are formed in a first metal layer, and the respective second elongated members of each of the fill cells are formed in a second metal layer above the first metal layer.

7. The chip of claim 6, wherein each of the fill cells has a metal density of between 15 percent to 30 percent in each of the first metal layer and the second metal layer.

8. The chip of claim 4, wherein, in each of the fill cells, a spacing between the respective first elongated members is greater than a width of each of the respective first elongated members, and a spacing between the respective second elongated members is greater than a width of each of the respective second elongated members.

9. The chip of claim 4, wherein each of the fill cells further comprises respective third elongated members extending over the respective second elongated members in the first direction, wherein the respective third elongated members are spaced apart in the second direction.

10. The chip of claim 9, wherein each of the fill cells further comprises:
respective first vias disposed between the respective first elongated members and the respective second elongated members; and
respective second vias disposed between the respective second elongated members and the respective third elongated members.

11. The chip of claim 9, wherein the respective first elongated members of each of the fill cells are formed in a first metal layer, the respective second elongated members of each of the fill cells are formed in a second metal layer above the first metal layer, and the respective third elongated members of each of the fill cells are formed in a third metal layer above the second metal layer.

12. The chip of claim 9, wherein each of the fill cells further comprises respective fourth elongated members extending over the respective third elongated members in the second direction, wherein the respective fourth elongated members are spaced apart in the first direction.

13. The chip of claim 12, wherein, in each of the fill cells, a spacing between the respective first elongated members is greater than a width of each of the respective first elongated members, a spacing between the respective second elongated members is greater than a width of each of the respective second elongated members, a spacing between the respective third elongated members is greater than a width of each of the respective third elongated members, and a spacing between the respective fourth elongated members is greater than a width of each of the respective fourth elongated members.

14. The chip of claim 12, wherein each of the fill cells further comprises:
respective first vias disposed between the respective first elongated members and the respective second elongated members;
respective second vias disposed between the respective second elongated members and the respective third elongated members; and
respective third vias disposed between the respective third elongated members and the respective fourth elongated members.

15. The chip of claim 12, wherein the respective first elongated members of each of the fill cells are formed in a first metal layer, the respective second elongated members of each of the fill cells are formed in a second metal layer above the first metal layer, the respective third elongated members of each of the fill cells are formed in a third metal layer above the second metal layer, and the respective third elongated members of each of the fill cells are formed in a fourth metal layer above the third metal layer.

16. The chip of claim 15, wherein each of the fill cells has a metal density of between 15 percent to 30 percent in each of the first metal layer, the second metal layer, the third metal layer, and the fourth metal layer.

17. The chip of claim 1, wherein the fill cells are disposed in a portion of the chip below an area surrounded by a loop of the first inductor.

18. The chip of claim 17, further comprising a second inductor overlapping the first inductor.

19. The chip of claim 17, wherein the first inductor comprises a planar loop inductor.

20. The chip of claim 17, wherein the first inductor comprises a spiral inductor.
